(19) United States
(12) Patent Application Publication
(10) Pub. No.: US 2016/0025871 A1
(43) Pub. Date: Jan. 28, 2016

(54) MAGNETRON SPUTTERING GUN ASSEMBLY

(71) Applicant: National Applied Research Laboratories, Taipei City (TW)

(72) Inventors: Bo-Huei Liao, Hsinchu City (TW); Chien-Nan Hsiao, Taichung City (TW)

(21) Appl. No.: 14/341,885

(22) Filed: Jul. 28, 2014

(51) Int. Cl. G01T 1/36; H01J 37/34

(52) U.S. Cl. CPC G01T 1/366; H01J 37/3405

(57) ABSTRACT

A magnetron sputtering gun device used in vacuum for sputtering to form a thin film, which comprises a magnet copper seat, a magnetic element, a conductive element, a sputtering target, a target fixation assembly, a cylinder-shape protection mask, and a sputtering inclination assembly. By enhancing the magnet copper seat, the magnetron sputtering gun device is equipped with capability of increased film coating speed and increased compound ability between the thin film and the reaction gas. A ferromagnetic material may be coated. The magnet copper seat may be designed so that the sputtering target and strong magnets therewithin may be conveniently detached. In this structure, a cooling water tubing and the strong magnets are separated, lengthening a lifetime of the strong magnets and protecting the strong magnets from demagnetization. The sputtering inclination assembly may further increase a uniformity of the thin film thickness.

### FIELD OF THE INVENTION

The present invention relates to a magnetron sputtering gun device, and particularly to a magnetron sputtering gun device capable of increasing a compound ability between a thin film and an interaction gas and increasing a film coating speed and an uniformity of a target and a thin film thickness.

### DESCRIPTION OF THE RELATED ART

A magnetron sputtering technology may form a thin film having a good fineness and adhesiveness owing to the high film forming energy. This feature has lent itself to be used in the application of coating of various thin films. However, the magnetron sputtering technology requires an expensive high frequency power source or an interactive sputtering technology, when forming a dielectric film.

The former has a slow film coating speed and involves a target expensive and fragile, while the latter has disadvantages of a poor compound ability between the thin film and the interaction gas and absorption resulted from an incomplete interaction owing to the use of the interactive sputtering. In addition, the magnetron sputtering used target has a low usage rate, resulting in a waste of the target.

A US patent, U.S. Pat. No. 4,162,954, shown in FIG. 10, discloses a technology where magnets are disposed in an inclination arrangement having an inclination angle of between 40 and 60 degrees. Plus that the interlocking stack posture of the S and N poles of the magnets may increase the uniformity of an etched area being sputtered by the target.

Another US patent, U.S. Pat. No. 5,262,028, disclosed such a technology where its magnets are arranged shown in FIG. 11, and such magnet arrangement may form four protruding magnetic line curves at upper, lower, left, and right sides, as shown in FIG. 11 and indicated as numerical labels 91, 92, 93, and 94. Within the four magnetic line curves, a magnetic line zero point 95 is formed, whereby increasing the uniformity of the etched area sputtered by the target.

U.S. Pat. No. 5,282,947 disclosed three magnets including side magnets 96, ring magnets 97, and central magnets 98, arranged as in FIG. 12. The side magnets 96 has an intensity of 350 to 450 Gauss, the central magnets have an intensity of 680 to 780 Gauss, and the ring magnet 1,350 to 1,450 Gauss. In this design, the etched area uniformity obtained by the target sputtering may be increased. Furthermore, rotating a magnetic seat may further benefit such uniformity. However, the above arrangement is too complicated and costly in its manufacturing, and involves a difficult maintenance. The magnets employed in such arrangement are generally heat-proof magnets, such as samarium-cobalt magnets, or magnets soaked in water for prevention of demagnetization. However, the water soaked magnets are weak in their force and the magnetic field intensity on the target surface may be reduced, resulting in a poor compound ability of the sputtering gun in the reactive sputtering process. Worse yet, a ferromagnetic material may not be coated by this sputtering technology. Therefore, the prior art technology may not satisfy the requirement of a user in a real use.

### SUMMARY OF THE INVENTION

It is, therefore, an object of the present invention to provide a magnetron sputtering gun device capable of increasing a compound ability between a thin film and an interaction gas and increasing a film coating speed and an uniformity of a target and a thin film thickness.

To achieve the above object, the magnetron sputtering gun device according to the present invention comprises a magnet copper seat, having a central magnet area, a periphery magnet area, and a hollow groove disposed between the periphery magnet area and the central magnet area; a magnetic element, detachably disposed between the periphery magnet area and the central magnet area; a conductive element, detachably disposed in the hollow; a sputtering target, disposed above the magnet copper seat; a target fixing assembly, covering the magnet copper seat and fixing the sputtering target; and a cylinder-shape protecting mask, covering the target fixing assembly.

In an embodiment, the magnetron sputtering gun device as claimed in claim 1, wherein a cooling water inlet hole is disposed rear to the magnet copper seat.

In an embodiment, the magnet element at the periphery magnet area has a magnet intensity of 5,400 to 6,000 Gauss ±20%.

In an embodiment, a sputtering inclination assembly disposed at a bottom of the target fixing assembly for providing an inclination.

In an embodiment, the magnet element is a plurality of magnets disposed co-axially between the periphery magnet area and the central magnet area.

In an embodiment, the peripheral magnet area and the central magnet area comprises a plurality of through-holes arranged peripherally.

1 In an embodiment, the conductive element comprises a thermo-conductive material, an electro-conductive material, and a magnetic conductivity material.

In an embodiment, the conductive element comprises a ferrimagnetic material, a ferromagnetic material, and a combination thereof.

In an embodiment, the ferromagnetic material is selected from a group consisting of iron (F), cobalt (Co), nickel (Ni), and a combination thereof.

In an embodiment, the ferromagnetic material is selected from a group consisting of aluminum (Al), copper (Cu), silver (Ag), zinc (Zn), gold (Au), carbon (C), lead (Pb), magnesium (Mg), platinum (Pt), chrome (Cr), manganess (Mn), tin (Sn), vanadium (V), tungsten (W), and a combination thereof.

### BRIEF DESCRIPTIONS OF THE DRAWINGS

FIG. 1 is an explosive diagram of a partial structure of a magnetron sputtering gun according to the present invention;

FIG. 2 is a schematic diagram of a rear view of a magnet copper seat according to the present invention;

FIG. 3 is a schematic diagram of an assembly between the magnet copper seat and a target fixation assembly;

FIG. 4 is a schematic diagram of an assembly between a cylinder-shape covering mask and a sputtering inclination assembly;

FIG. 5 is a schematic diagram of the magnet copper seat used in a non-balance according to the present invention;

FIG. 6 is a schematic diagram of non-balance magnetic lines according to the present invention;

FIG. 7 is a schematic diagram of a transmittance of silicon nitride in the cases of different non-balance sputtering coefficients according to the present invention;

FIG. 8 is a schematic diagram of a comparison between the magnetic force lines of copper or ferromagnetic material according to the present invention.

FIG. 9 is a schematic diagram of a uniformity of a thin TiO₂ film thickness according to the present invention;

FIG. 10 is a schematic diagram of a prior art magnetron sputtering device;

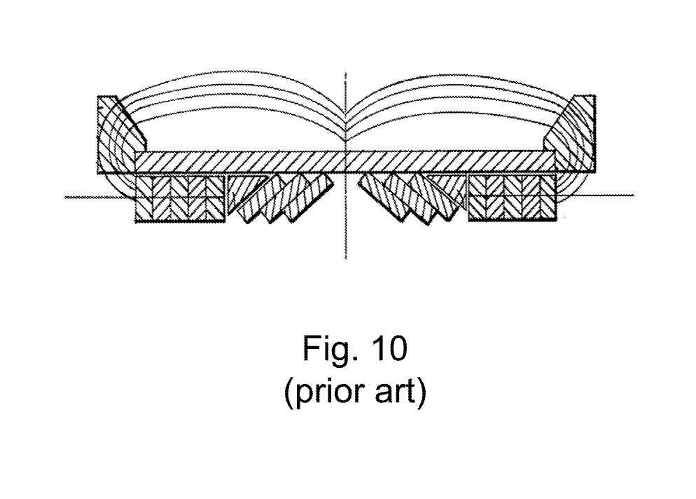

FIG. 11 is a schematic diagram of magnetic force line curves obtained from another prior art magnetron sputtering device; and

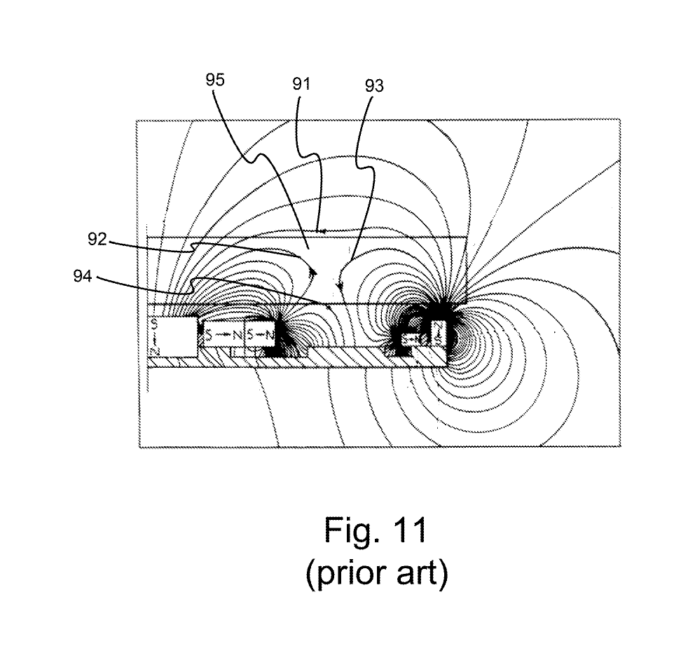

FIG. 12 is a schematic diagram of still another magnetron sputtering device.

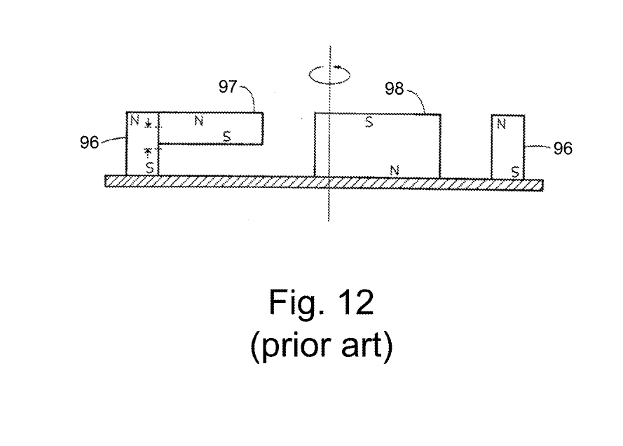

### DESCRIPTION OF THE PREFERRED EMBODIMENTS

The present invention will be better understood from the following detailed descriptions of the preferred embodiments according to the present invention, taken in conjunction with the accompanying drawings, in which:

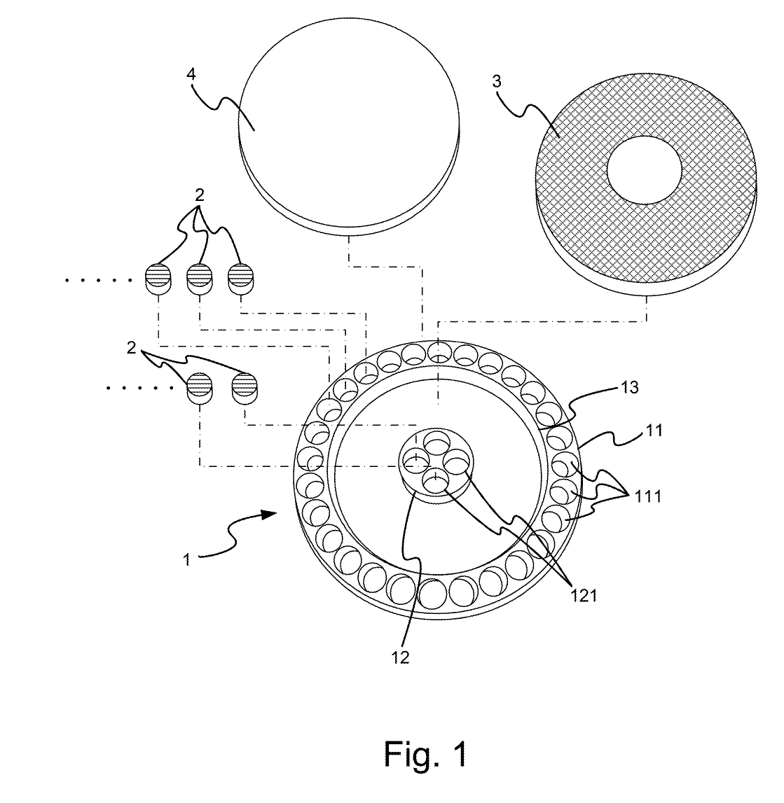

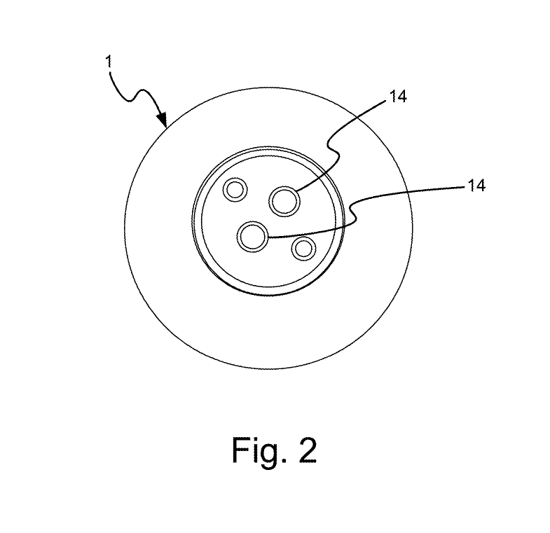

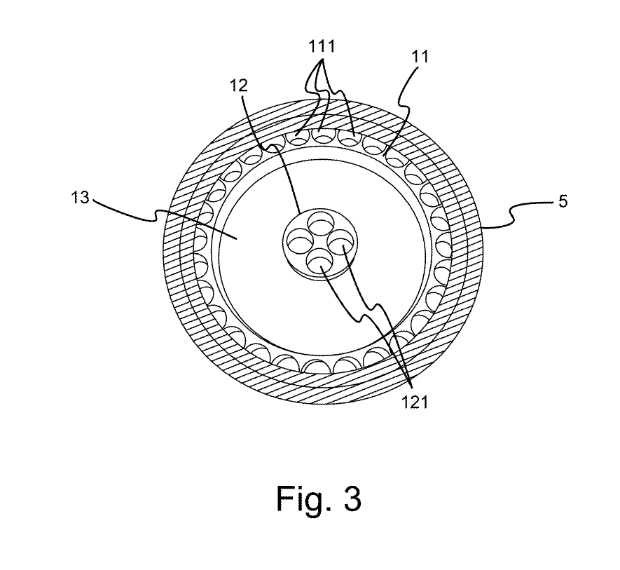

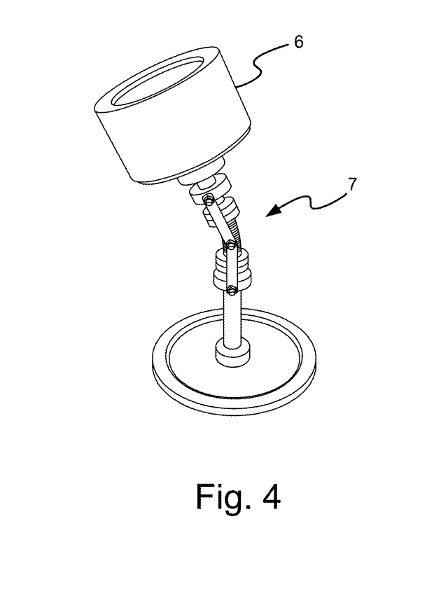

Referring to FIG. 1 to FIG. 4, in which FIG. 1 is an explosive diagram of a partial structure of a magnetron sputtering gun according to the present invention, FIG. 2 is a schematic diagram of a rear view of a magnet copper seat according to the present invention, FIG. 3 is a schematic diagram of an assembly between the magnet copper seat and a target fixation assembly, and FIG. 4 is a schematic diagram of an assembly between a cylinder-shape covering mask and a sputtering inclination assembly.

As shown in the figures, the magnetron sputtering gun device used in a vacuum for sputtering to form a thin film.

The magnetron sputtering gun device comprises a magnet copper seat 1, a magnetic element 2, a conductive element 3, a sputtering target 4, a target fixation assembly 5, a cylinder-shape protection mask 6, and a sputtering inclination assembly 7.

The mentioned magnet copper seat 1 has a peripheral magnet area 11, a central magnet area 12, and a hollow groove 13 disposed between the peripheral magnet area 11 and the central magnet area 12.

The peripheral magnet area 11 and the central magnetic area 12 each comprise a plurality of through-holes 111, 121 arranged in a ring shape. Rear to the magnetic copper seat 1, a cooling water inlet hole 14 is additionally disposed.

The magnetic element 2 is detachably disposed at the peripheral magnet area 11 and the central magnet area 12, and is a plurality of magnets co-axially within the through-holes 111, 121 between the periphery magnet area 11 and the central magnet area 12. The magnetic element 2 located at the peripheral magnet area 11 has a magnetic intensity of 5,400 to 6,000 Gauss±20%.

The conductive element 3 is detachably disposed within the hollow groove 13 and may be replaced with a thermo-conductive, an electro-conductive or a magnet-conductive material, to increase a use rate of the sputtering target 4. In an embodiment, the conductive element 3 may be a ferromagnetic material, a ferromagnetic material or a combination thereof. The ferromagnetic material may be selected from a group consisting of iron (F), cobalt (Co), nickel (Ni), and a combination thereof. The ferromagnetic material may be selected from a group consisting of aluminum (Al), copper (Cu), silver (Ag), zinc (Zn), gold (Au), carbon (C), lead (Pb), magnesium (Mg), platinum (Pt), chrome (Cr), manganess (Mn), tin (Sn), vanadium (V), tungsten (W), and a combination thereof.

The sputtering target 4 is disposed above the magnet copper seat 1. The target fixation assembly 5 covers the magnet copper seat 1 and fixes the sputtering target 4, and is then covered by the cylinder-shape protection mask 6. The sputtering inclination assembly 7 is disposed at a bottom side of the target fixation assembly 5 to provide an inclination. As such, a novel magnetron sputtering gun device is constituted by the above described structure.

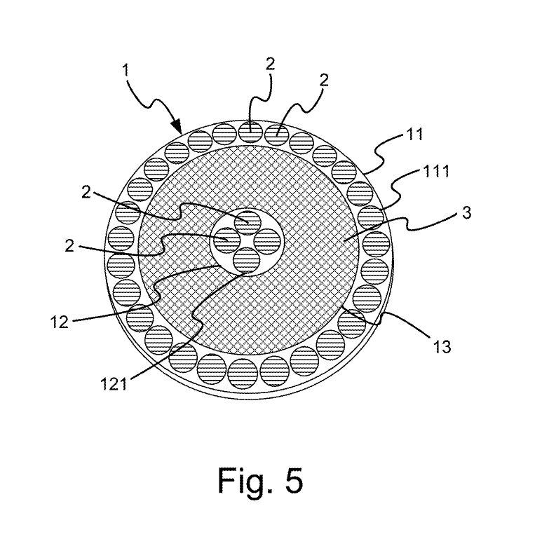

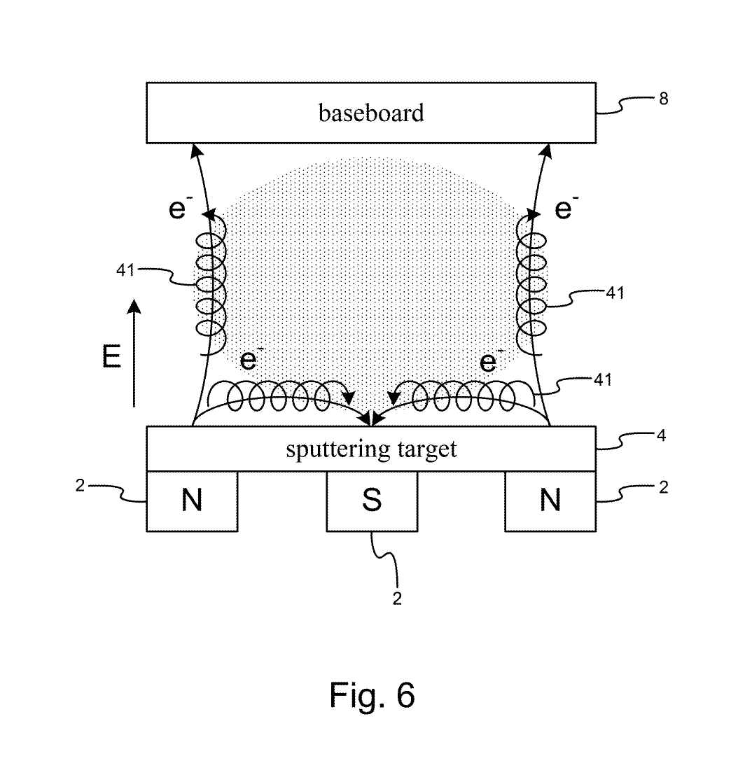

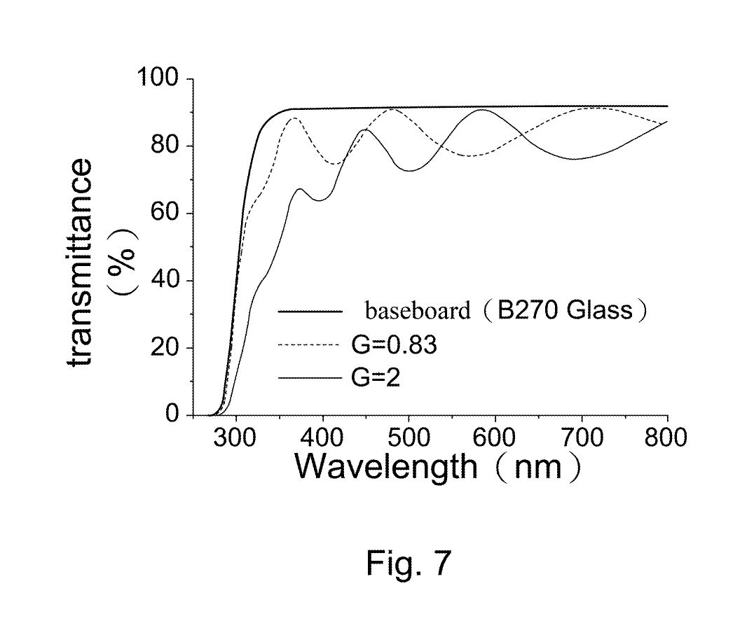

Referring to FIG. 5 to FIG. 7, in which FIG. 5 is a schematic diagram of the magnet copper seat used in a non-balance according to the present invention, FIG. 6 is a schematic diagram of non-balance magnetic lines according to the present invention, and FIG. 7 is a schematic diagram of a transmittance of silicon nitride in the cases of different non-balance sputtering coefficients according to the present invention. In the course of sputtering, the magnetic element 2 is disposed at the peripheral area 11 and the central magnet area 12 or only the peripheral magnet area 11. And, the conductive element 3 is disposed at the hollow groove 13, as shown in FIG. 5. Further, a non-conductive copper is taken as the conductive element 3, which may form a non-balance magnetic force lines shown in FIG. 6. The magnetic force lines 41 run apart from the sputtering target 4 may extend to a baseboard 8, and deionize a reaction gas adjacent to the sputtering target 4 and also a reaction gas nearby the baseboard 8. In this manner, the thin film may have a more complete compound reaction.

In this embodiment, a sputtering of silicon nitride (coating of a non-metal) is exemplified, as shown in FIG. 7. In the figure, dash lines indicate the technology of the present invention, and it is pointed out that a variation of magnet strength and arrangement may form a non-balance magnetron sputtering and increase the thin film's compound reaction, and thus increasing a transmittance. It may be evidenced that the magnetron sputtering gun device may increase a compound ability between the thin fill, and the reaction gas.

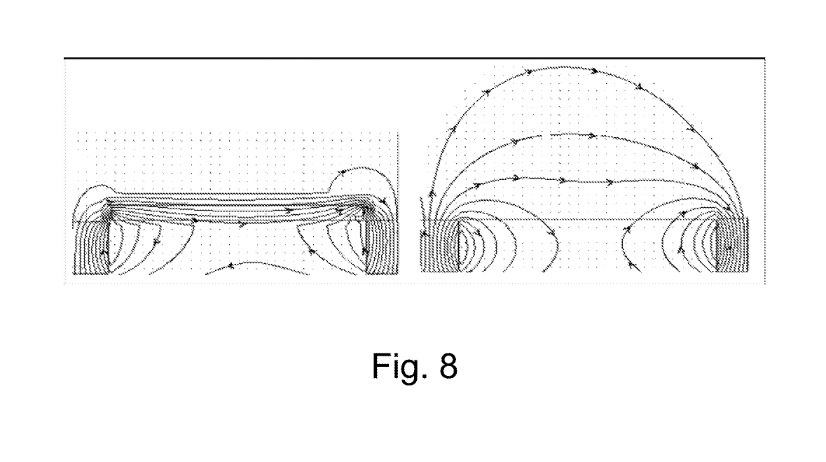

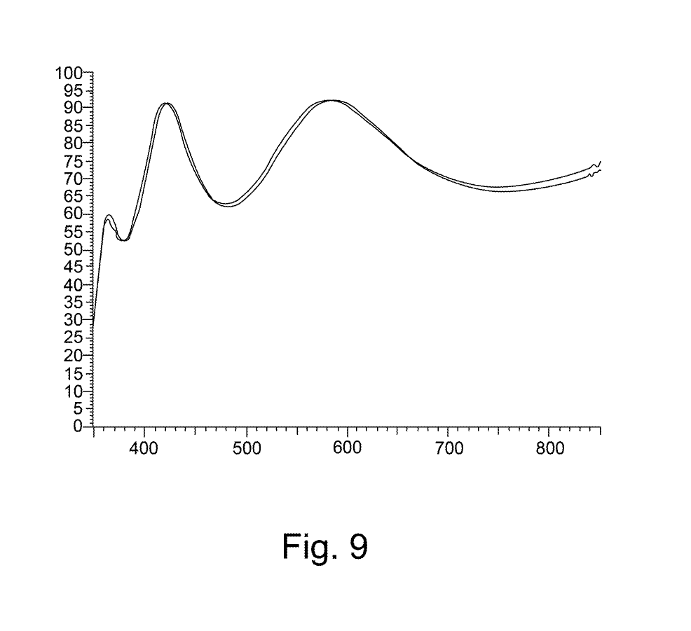

Referring to FIG. 8 and FIG. 9, in which FIG. 8 is a schematic diagram of a comparison between the magnetic force lines of copper or ferromagnetic material according to the present invention, and FIG. 9 is a schematic diagram of a uniformity of a thin TiO₂ film thickness according to the present invention. As shown, when it is desired to increase the uniformity of the etched area subject to the target sputtering, the conductive element is a ferromagnetic material. In this embodiment, the conductive element may also be a proportional combination of copper or a ferromagnetic material, and molybdenum (Mb) is adopted as the target.

As shown in FIG. 8, at the left side is magnetic force curves of the present invention. At this time, the magnetron sputtering gun device may let the magnetic force lines parallel with above the target. As compared to the conventional magnetic force curves at the right side, the present invention may increase the uniformity of the etched area on the thin film formed by the sputtering process. Furthermore, under the conditions of identical film coating power and work gas, the magnetron sputtering gun device with the ferromagnetic material may have a larger plasma sputtering ring and Mb film thickness, representing an evidence that the magnetron sputtering gun device of the present invention may have an increased film coating speed.

In addition, to promote the film thickness uniformity, the present invention may be further provided with a sputtering inclination assembly 7, as is shown in FIG. 4. This sputtering inclination assembly 7 may sputter the TiO₂ film in an inclination direction. It is known by experiments that a proper inclination of the magnetron sputtering gun device may achieve in a good uniformity of the thin film thickness, as shown in FIG. 9. And, the uniformity on a four inches substrate is (243.97−242.98)/(243.97+242.98)=0.2%, which indicates the magnetron sputtering gun device of the present invention may increase the thin film thickness uniformity.

As such, the present invention enhances the magnet copper seat so that the magnetron sputtering gun device has an increased film coating speed and an increased compound ability between the thin film and reaction gas. A ferromagnetic material may be coated. The magnet copper seat may be designed so that the sputtering target and strong magnets therewithin may be conveniently detached. In this structure, a cooling water tubing and the strong magnets are separated, lengthening a lifetime of the strong magnets and protecting the strong magnets from demagnetization. The sputtering inclination assembly may further increase the uniformity of the thin film thickness.

In view of the above, the magnetron sputtering gun device may effectively improve the disadvantages has an increased film coating speed and an increased compound ability between the thin film and reaction gas. A ferromagnetic material may be coated. The magnet copper seat may be designed so that the sputtering target and strong magnets therewithin may be conveniently detached. In this structure, the cooling water tubing and the strong magnets are separated, lengthening a lifetime of the strong magnets and protecting the strong magnets from demagnetization. The sputtering inclination assembly may further increase a uniformity of the thin film thickness.

From all these views, the present invention may be deemed as being more effective, practical, useful for the consumer's demand, and thus may meet with the requirements for a patent.

The above described is merely examples and preferred embodiments of the present invention, and not exemplified to intend to limit the present invention. Any modifications and changes without departing from the scope of the spirit of the present invention are deemed as within the scope of the present invention. The scope of the present invention is to be interpreted with the scope as defined in the claims.

What is claimed is:

1. An imbedded mobile detection device, comprising:
a radiation detector, comprising a detection crystal and a photo-sensitive element, for effectively absorbing a species and an energy range of radioactive particles of a predetermined detection object, and generating an analog pulse signal based thereon, wherein the detection crystal is a C:Al₂O₃ crystal having oxygen vacancy deficiencies formed by subjecting a carbon covered Al₂O₃ structure to vacuum diffusion and atmosphere annealing, when any radioactive particle exists in an on-spot environment, an energy thereof is absorbed through a recombination process of the vacancy deficiencies, and the photo-sensitive element converts photo-pulses generated by the detection crystal having absorbed the energy of the radioactive particles into an analog pulse signal;
an analog-digital converter (ADC), coupled to the radiation detector and converting the analog pulse signal into a digital logic pulse signal; and
a software application unit, coupled to the ADC and receiving and computing the digital logic pulse signal by using a software setting function thereof, executing a radiation energy spectrum calculation and a nuclide comparison program, acquiring a radiation energy spectrum analysis information, so that a measurement result is online processed and a species of the nuclide is accurately determined.

2. The imbedded mobile detection device as claimed in claim 1, wherein the radioactive particles are α-particles, β-particles, or γ-particles.

3. The imbedded mobile detection device as claimed in claim 1, wherein the photo-sensitive element is one of a photodiode and a photomultiplier.

4. The imbedded mobile detection device as claimed in claim 1, wherein when the on-spot environment has the radioactive particles, in the detection crystal electrons at a valence band (VB) jump onto a conduction band, the electrons are trapped at a defect band (DB) having a lower energy level E1, the trapped electrons at the DB is excited to a conduction band by activating a long wavelength light source, the excited electrons releases an energy thereof onto an energy level E2 lower than the DB, so that the energy of the radioactive particles has an absorption through a deficiency recombination process.

5. The imbedded mobile detection device as claimed in claim 4, wherein the energy level E1 is greater than the energy level E2.

6. The imbedded mobile detection device as claimed in claim 4, wherein the shorter wavelength light source includes a green light emitting diode (LED), a blue LED, and a violet LED.

7. The imbedded mobile detection device as claimed in claim 1, wherein the software application unit has a plurality of software setting functions including calculation, recordation, display, and data transmission for measuring a pulse width count of the digital logic pulse signal to produce an energy count information as the pulse width measurement result, by which the radiation energy spectrum calculation and the nuclide comparison program including a nuclide species identification and an activeness computation are executed according to a user's command, and finally a background noise is filtered out to obtain the radiation energy spectrum analysis information.

8. The imbedded mobile detection device as claimed in claim 1, including a smart mobile phone, a digital camera, a digital video-recorder, a portable multi-media play, a portable navigation device, a personal digital assistant (PDA), a digital photo frame, and a mobile networking device.
